(19) United States
(12) Patent Application Publication
(10) Pub. No.: US 2018/0286702 A1
(43) Pub. Date: Oct. 4, 2018

(54) SEMICONDUCTOR DEVICE AND METHOD OF MANUFACTURING THE SAME

(71) Applicant: TOYOTA JIDOSHA KABUSHIKI KAISHA, Toyota-shi (JP)

(72) Inventors: Takanori KAWASHIMA, Anjo-shi (JP); Hirotaka OHNO, Miyoshi-shi (JP)

(73) Assignee: TOYOTA JIDOSHA KABUSHIKI KAISHA, Toyota-shi (JP)

(21) Appl. No.: 15/902,479

(22) Filed: Feb. 22, 2018

(30) Foreign Application Priority Data
Mar. 29, 2017 (JP) 2017-065283

(51) Int. Cl. H01L 21/48; H01L 23/495; H01L 23/00

(52) U.S. Cl. CPC H01L 21/4825; H01L 2224/83136; H01L 24/83; H01L 23/495

(57) ABSTRACT

A method of manufacturing a semiconductor device by connecting a semiconductor chip to a lead frame using a jig, the semiconductor chip including a main electrode provided at a surface of the semiconductor chip, the lead frame including a connection projecting portion and a positioning portion, the positioning portion including at least one of a convex shape and a concave shape provided around the connection projecting portion, the method may include: engaging the jig to the positioning portion in a state where a clearance is provided between the connection projecting portion and the jig; engaging the jig to the semiconductor chip; and connecting the connection projecting portion to the main electrode of the semiconductor chip via solder in a state where the jig is engaged to the positioning portion and the semiconductor chip.

### TECHNICAL FIELD

A technique disclosed herein relates to a semiconductor device and a method of manufacturing the same.

### BACKGROUND

Japanese Patent Application Publication No. 2009-146950 describes a semiconductor device in which a lead frame includes a connection projecting portion and the connection projecting portion is connected to a main electrode of a semiconductor chip. Due to the connection projecting portion of the lead frame, a space for disposing signal wiring is secured. By inserting a positioning pin into the lead frame, misalignment between the semiconductor chip and the lead frame is suppressed.

### SUMMARY

In a case of adopting a lead frame including a connection projecting portion as in Japanese Patent Application Publication No. 2009-146950, misalignment may occur upon when the connection projecting portion is soldered to a main electrode. When a position of the connection projecting portion of the lead frame misaligns with respect to the main electrode of a semiconductor chip, it becomes difficult for heat to be transferred to the lead frame from the semiconductor chip. As a result, heat dissipating performance of the semiconductor device is deteriorated. In a method described in Japanese Patent Application Publication No. 2009-146950, a lead frame needs to be provided with a hole into which a pin is inserted, and thus heat dissipation is hindered at a position of the hole. Therefore, the disclosure herein provides a technique capable of positioning a lead frame and a semiconductor chip with respect to each other, without hindering heat dissipation.

A method of manufacturing a semiconductor device disclosed herein connects a semiconductor chip to a lead frame using a jig. The semiconductor chip may comprise a main electrode provided at a surface of the semiconductor chip. The lead frame may comprise a connection projecting portion and a positioning portion, and the positioning portion may include at least one of a convex shape and a concave shape provided around the connection projecting portion. The method may comprise: engaging the jig to the positioning portion in a state where a clearance is provided between the connection projecting portion and the jig; engaging the jig to the semiconductor chip; and connecting the connection projecting portion to the main electrode of the semiconductor chip via solder in a state where the jig is engaged to the positioning portion and the semiconductor chip.

In this manufacturing method, the jig is engaged to the positioning portion of the lead frame, and thus misalignment between the lead frame and the jig is suppressed. Further, the jig is also engaged to the semiconductor chip, and thus misalignment between the semiconductor chip and the jig is suppressed as well. Due to this, the lead frame and the semiconductor chip are positioned with respect to each other via the jig. Therefore, misalignment between the lead frame and the semiconductor chip is suppressed. In the state where the lead frame and the semiconductor chip are positioned with respect to each other via the jig as described above, the main electrode of the semiconductor chip is connected to the connection projecting portion of the lead frame via solder. Thereby, the connection projecting portion is suppressed from misaligning with respect to the main electrode, and deterioration in heat dissipating performance of the semiconductor device can be prevented. Further, in this method, the positioning portion includes the convex shape or the concave shape, and thus heat dissipation is not hindered at the positioning portion. Therefore, according to this manufacturing method, a semiconductor device with high heat dissipating performance can be stably manufactured.

Further, the disclosure herein provides a semiconductor device with high heat dissipating performance. This semiconductor device may comprise a semiconductor chip including a main electrode provided at a surface of the semiconductor chip and a lead frame. The lead frame may include a connection projecting portion, and a positioning portion including at least one of a convex shape and a concave shape provided around the connection projecting portion. The connection projecting portion may be connected to the main electrode via solder.

This semiconductor device can be manufactured by the aforementioned manufacturing method disclosed herein. Since the positioning portion includes the convex shape or the concave shape in this semiconductor device, heat dissipation is not hindered at the positioning portion, and the semiconductor device exhibits high heat dissipating performance.

### BRIEF DESCRIPTION OF DRAWINGS

FIG. 1 is a perspective view of a lead frame;

FIG. 2 is an enlarged plan view of a main terminal of the lead frame;

FIG. 3 is a cross sectional view along a line III-III in FIGS. 1 and 2;

FIG. 4 is a cross sectional view along a line IV-IV in FIGS. 1 and 2;

FIG. 5 is a perspective view of the lead frame with a jig attached;

FIG. 6 is an enlarged plan view of the main terminal with the jig attached, corresponding to FIG. 2;

FIG. 7 is a cross sectional view of the lead frame with the jig attached, corresponding to FIG. 3;

FIG. 8 is a cross sectional view of the lead frame with the jig attached, corresponding to FIG. 4;

FIG. 9 is an enlarged plan view of a semiconductor chip and the lead frame after positioning, corresponding to FIG. 2;

FIG. 10 is a cross sectional view of the semiconductor chip and the lead frame after positioning, corresponding to FIG. 3;

FIG. 11 is a cross sectional view of the semiconductor chip and the lead frame after positioning, corresponding to FIG. 4;

FIG. 12 is a cross sectional view of the semiconductor chip and the lead frame after reflow, corresponding to FIG. 3;

FIG. 13 is a cross sectional view of the semiconductor chip and the lead frame after reflow, corresponding to FIG. 4;

FIG. 14 is a cross sectional view of a semi-manufactured product after a collector terminal has been connected, corresponding to FIG. 3;

FIG. 15 is a cross sectional view of the semi-manufactured product after an insulating resin layer has been formed, corresponding to FIG. 3;

FIG. 16 is a plan view of the semi-manufactured product after the insulating resin layer has been formed;

FIG. 17 is a plan view of a semiconductor device manufactured by a manufacturing method of an embodiment;

FIG. 18 is an explanatory diagram for a conventional manufacturing method;

FIG. 19 is an explanatory diagram for the conventional manufacturing method;

FIG. 20 is a plan view of a semiconductor device manufactured by the conventional manufacturing method;

FIG. 21 is a cross sectional view showing a solder layer with large misalignment;

FIG. 22 is a plan view showing a positioning convex portion of a variant;

FIG. 23 is a cross sectional view showing the positioning convex portion of the variant;

FIG. 24 is a cross sectional view showing a positioning convex portion of another variant;

FIG. 25 is a cross sectional view showing the positioning convex portion of the other variant;

FIG. 26 is a plan view showing a positioning convex portion of yet another variant;

FIG. 27 is a plan view showing a positioning convex portion of a variant;

FIG. 28 is a plan view showing a positioning convex portion of another variant;

FIG. 29 is a plan view showing a positioning convex portion of yet another variant;

FIG. 30 is a plan view showing a positioning convex portion of a variant;

FIG. 31 is a plan view showing a positioning convex portion of another variant;

FIG. 32 is a plan view showing a positioning convex portion of yet another variant;

FIG. 33 is a plan view showing a positioning convex portion of a variant;

FIG. 34 is a plan view showing a positioning convex portion of another variant; and

FIG. 35 is a cross sectional view showing a positioning concave portion of yet another variant.

### DETAILED DESCRIPTION

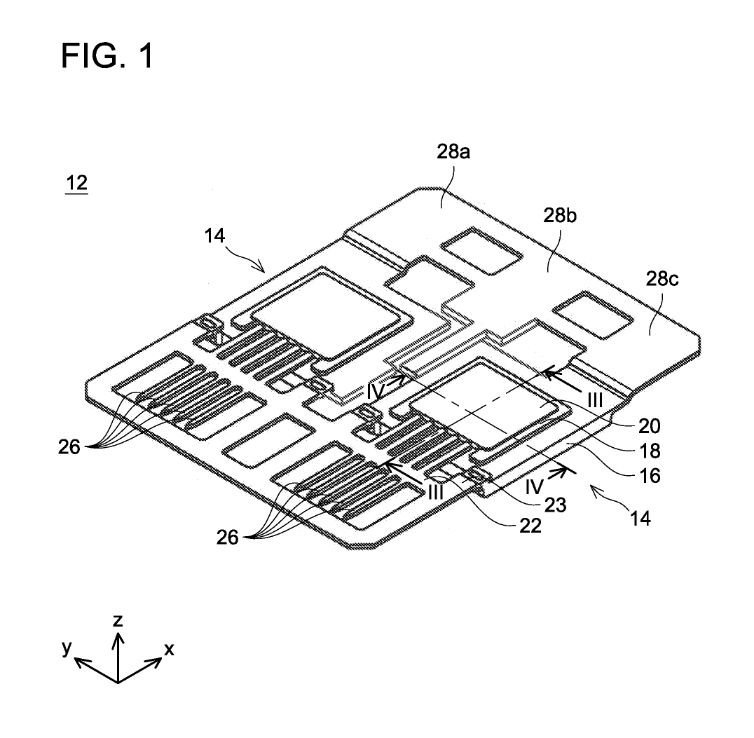

A manufacturing method of a semiconductor device of an embodiment will be described. FIGS. 1 to 4 show a lead frame 12 to be used in the manufacturing method of the embodiment. The lead frame 12 is a component in which a plurality of terminals for connecting to a semiconductor chip is connected to each other. The lead frame 12 comprises two die pads 14, main terminals 28a to 28c, and a plurality of signal terminals 26. A semiconductor chip is connected to each of the die pads 14. The main terminals 28a, 28c are connected to their corresponding die pads 14, respectively. The main terminal 28b is connected to a collector terminal 60 to be described later. It should be noted that the two die pads 14 are substantially identical in terms of their configurations and methods of use, and thus the following description will proceed focusing on only one of the die pads 14 (the die pad 14 on the right side in FIG. 1).

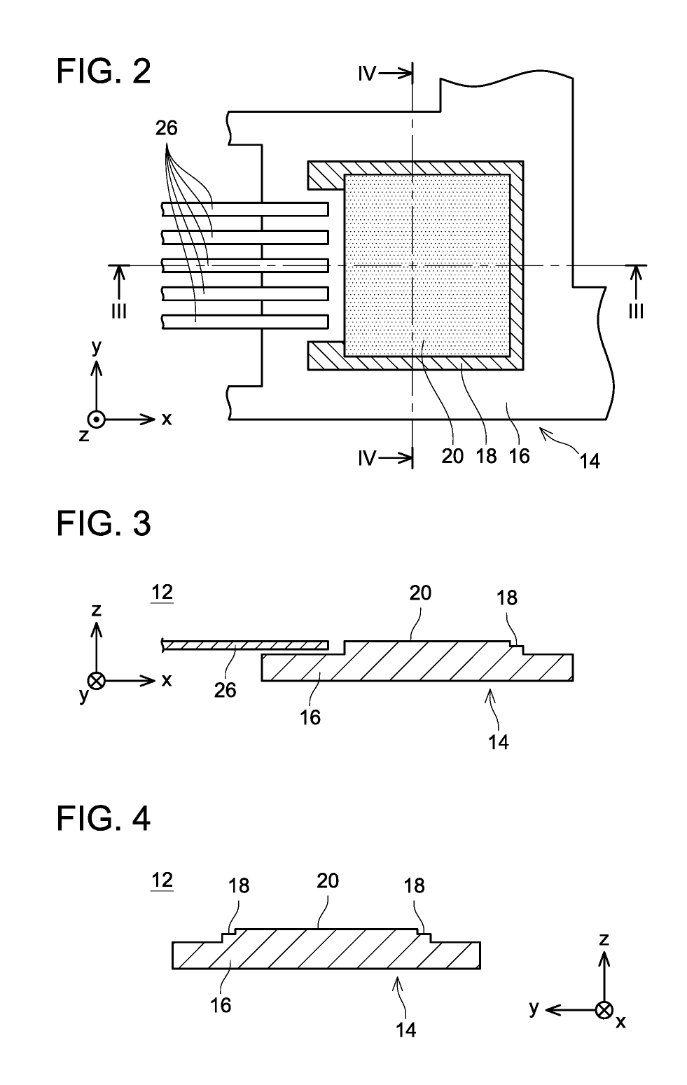

The die pad 14 includes a heat dissipating plate 16, a positioning convex portion 18, and a connection projecting portion 20. In FIG. 2 and subsequent enlarged plan views, the positioning convex portion 18 is hatched with oblique lines, and the connection projecting portion 20 is hatched with dots. The heat dissipating plate 16 is a plate-shaped portion having a thicker thickness than other portions of the lead frame 12. Hereinbelow, a thickness direction of the heat dissipating plate 16 will be termed a z-direction, one direction perpendicular to the z-direction will be termed an x-direction, and a direction perpendicular to the x-direction and the z-direction will be termed a y-direction. The positioning convex portion 18 is a portion projecting upward from an upper surface of the heat dissipating plate 16. As shown in FIG. 2, in a view along the z-direction, the positioning convex portion 18 has a substantially quadrangular shape. The connection projecting portion 20 is a portion projecting further upward from an upper surface of the positioning convex portion 18. As shown in FIG. 2, in the view along the z-direction, the connection projecting portion 20 has a quadrangular shape. As shown in FIGS. 2 and 3, the plurality of signal terminals 26 is arranged adjacent to one side of the connection projecting portion 20. The respective signal terminals 26 extend long in the x-direction, and are arranged in the y-direction with intervals therebetween. One end of each signal terminal 26 is arranged above the heat dissipating plate 16. A clearance is provided between the signal terminals 26 and the die pad 14. As shown in FIG. 1, the signal terminals 26 are connected to each other by a tie bar 22. Further, the signal terminals 26 are connected to the die pad 14 by the tie bar 22 and a suspension lead 23. As shown in FIG. 2, the positioning convex portion 18 is not arranged at a position facing the signal terminals 26. Except at the position facing the signal terminals 26, the positioning convex portion 18 is arranged to surround the connection projecting portion 20.

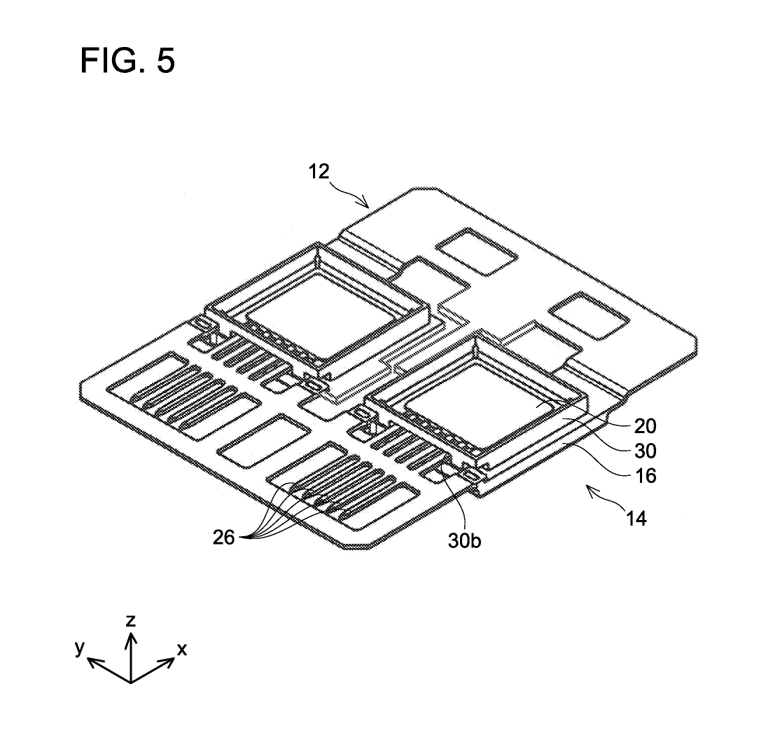

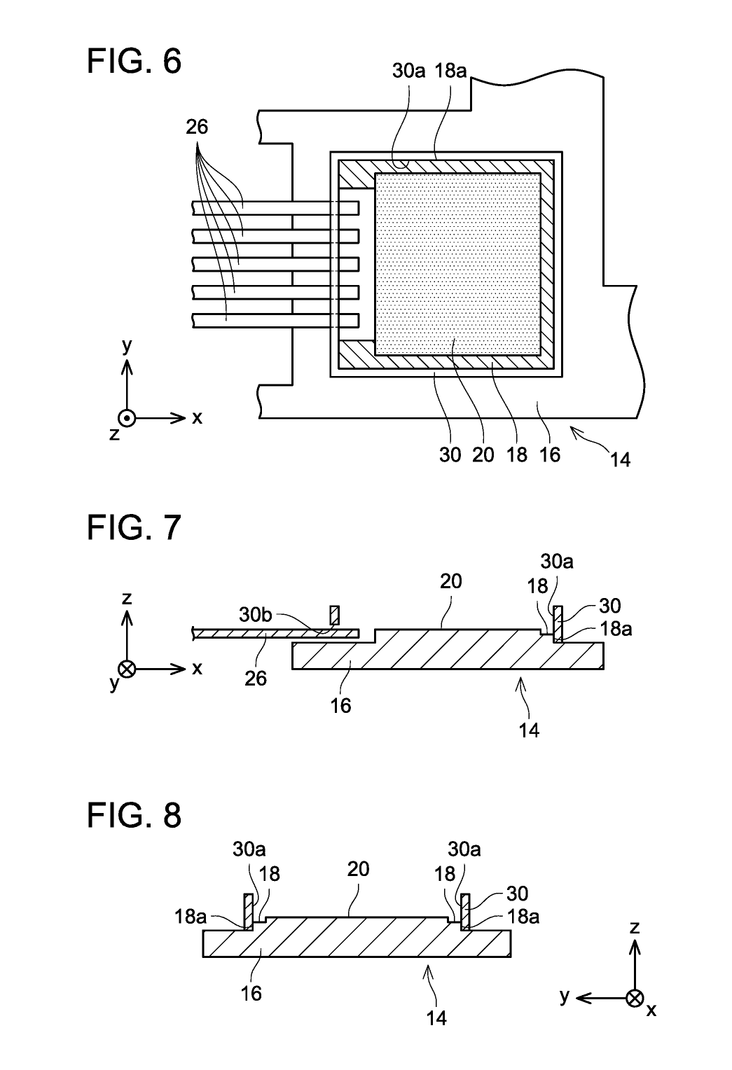

In the manufacturing method of the present embodiment, a step of attaching a jig is firstly performed. In the step of attaching a jig, a jig 30 is attached to the lead frame 12 as shown in FIGS. 5 to 8. The jig 30 has a quadrangular ring shape as its cross sectional shape. As shown in FIG. 6, the jig 30 is engaged to the positioning convex portion 18 such that an inner peripheral surface 30a of the jig 30 comes to be in tight contact with an outer peripheral surface 18a of the positioning convex portion 18. Thereby, the jig 30 is accurately positioned with respect to the lead frame 12. As shown in FIGS. 5 and 7, a notch 30b is provided at a part of a lower surface of the jig 30. When the jig 30 is attached to the lead frame 12, the notch 30b is arranged at a position corresponding to the plurality of signal terminals 26. Since the notch 30b is provided, the jig 30 does not make contact with the signal terminals 26. As shown in FIG. 6, a clearance is provided between the jig 30 and the connection projecting portion 20. As shown in FIGS. 7 and 8, a height of the jig 30 is higher than a height of the connection projecting portion 20.

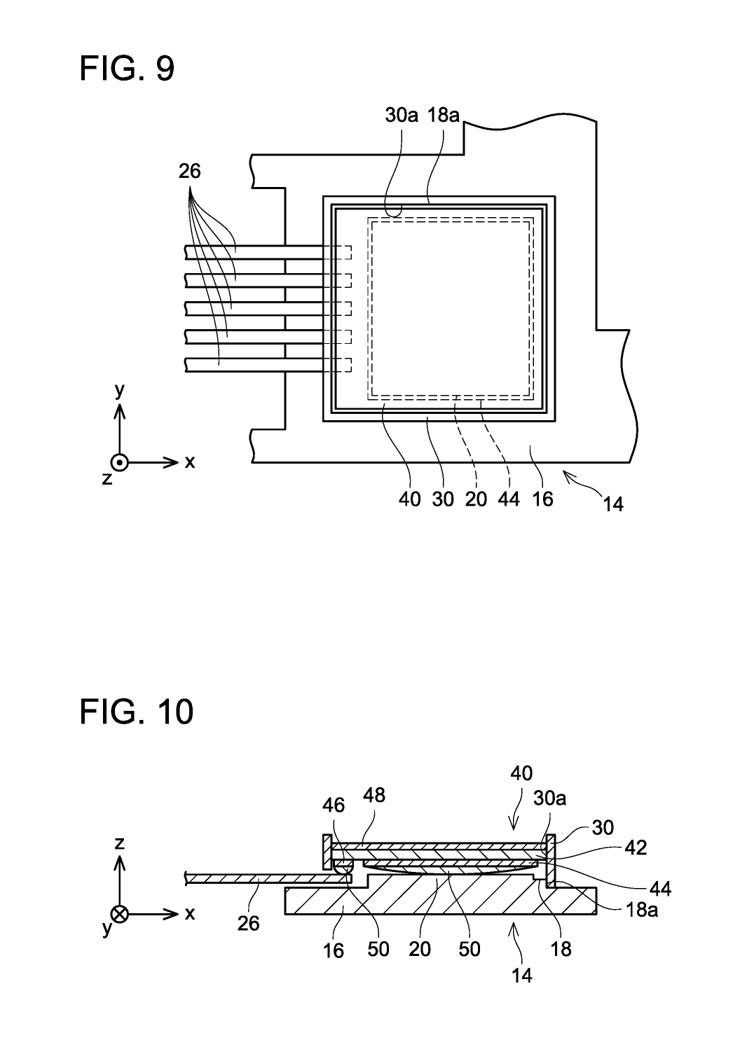

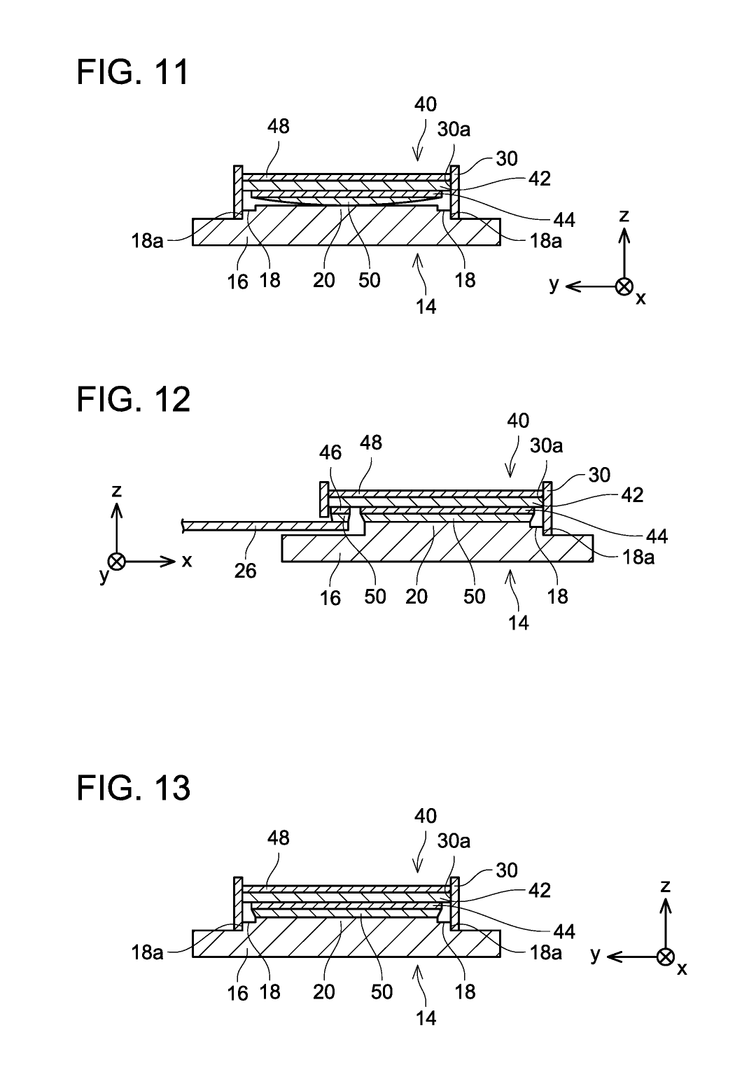

Next, a step of arranging a semiconductor chip is performed. In the step of arranging a semiconductor chip, as shown in FIGS. 9 to 11, a semiconductor chip 40 is arranged within the jig 30. That is, the jig 30 is engaged to the semiconductor chip 40. First, the semiconductor chip 40 will be described. As shown in FIGS. 10 and 11, the semiconductor chip 40 includes a semiconductor substrate 42, an emitter electrode 44, signal electrodes 46, and a collector electrode 48. An IGBT (Insulated Gate Bipolar Transistor) is provided in the semiconductor substrate 42. The emitter electrode 44 and the signal electrodes 46 are provided on a first surface of the semiconductor substrate 42 (a lower surface thereof in FIGS. 10 and 11). It should be noted, although only one signal electrode 46 is shown in FIG. 10, the semiconductor chip 40 includes multiple signal electrodes 46 in a number corresponding to a number of the signal terminals 26 (e.g., five). The signal electrodes 46 are arranged at a position adjacent to the emitter electrode 44. The emitter electrode 44 is much larger than each signal electrode 46. The signal electrodes 46 are a gate electrode of the IGBT, an electrode for temperature detection, an electrode for current detection, an electrode for voltage detection, and the like. A signal having a potential of the emitter electrode 44 as a reference potential is applied to the signal electrodes 46. Therefore, a potential difference between the signal electrodes 46 and the emitter electrode 44 is small. The collector electrode 48 covers an entirety of a second surface of the semiconductor substrate 42 (a surface thereof on an opposite side to the first surface, which is an upper surface in FIGS. 10, 11).

In the step of arranging a semiconductor chip, the semiconductor chip 40 is inserted into the jig 30 from above, with the emitter electrode 44 oriented downward. Due to this, the semiconductor chip 40 is arranged within the jig 30. Here, as shown in FIG. 10, the semiconductor chip 40 is set such that the emitter electrode 44 is arranged above the connection projecting portion 20, and each signal electrode 46 is arranged above the end of its corresponding signal terminal 26. At this occasion, solder layers 50 are interposed between the emitter electrode 44 and the connection projecting portion 20, and between each signal electrode 46 and its corresponding signal terminal 26. As shown in FIG. 9, in the view along the z-direction, a contour of the semiconductor chip 40 is slightly smaller than a contour (i.e., the outer peripheral surface 18a) of the positioning convex portion 18. Thus, the semiconductor chip 40 is slightly smaller than the inner peripheral surface 30a of the jig 30. Due to this, when the semiconductor chip 40 is arranged within the jig 30, the semiconductor chip 40 is suppressed from being subjected to a high load applied by the jig 30. Therefore, the semiconductor substrate 42 is suppressed from being cracked or chipped. In the step of arranging a semiconductor chip, a peripheral surface of the semiconductor chip 40 is guided by the inner peripheral surface 30a of the jig 30, and thus the semiconductor chip 40 is positioned with respect to the jig 30. That is, the semiconductor chip 40 is positioned with respect to the lead frame 12 via the jig 30. In FIG. 9, the connection projecting portion 20 and the emitter electrode 44 are shown by broken lines. As shown in FIG. 9, in the view along the z-direction, an entirety of an upper surface of the connection projecting portion 20 is arranged within a contour of the emitter electrode 44. By using the jig 30, the emitter electrode 44 and the connection projecting portion 20 can be accurately positioned with respect to each other as shown in FIG. 9.

Next, a reflow step is performed. In the reflow step, a stack body which has been assembled as shown in FIGS. 9 to 11 is put through a reflow furnace. Due to this, the stack body is once heated, and thereafter, it is cooled down to a room temperature. When the stack body is heated, the solder layers 50 melt. Then, when the stack body is cooled, the solder layers 50 solidify. As a result, as shown in FIGS. 12 and 13, the emitter electrode 44 is connected to the connection projecting portion 20 by the solder layer 50, and the signal electrodes 46 are also connected to their corresponding signal terminals 26 by the solder layers 50. After the reflow step, the jig 30 is detached from the lead frame 12 and the semiconductor chip 40.

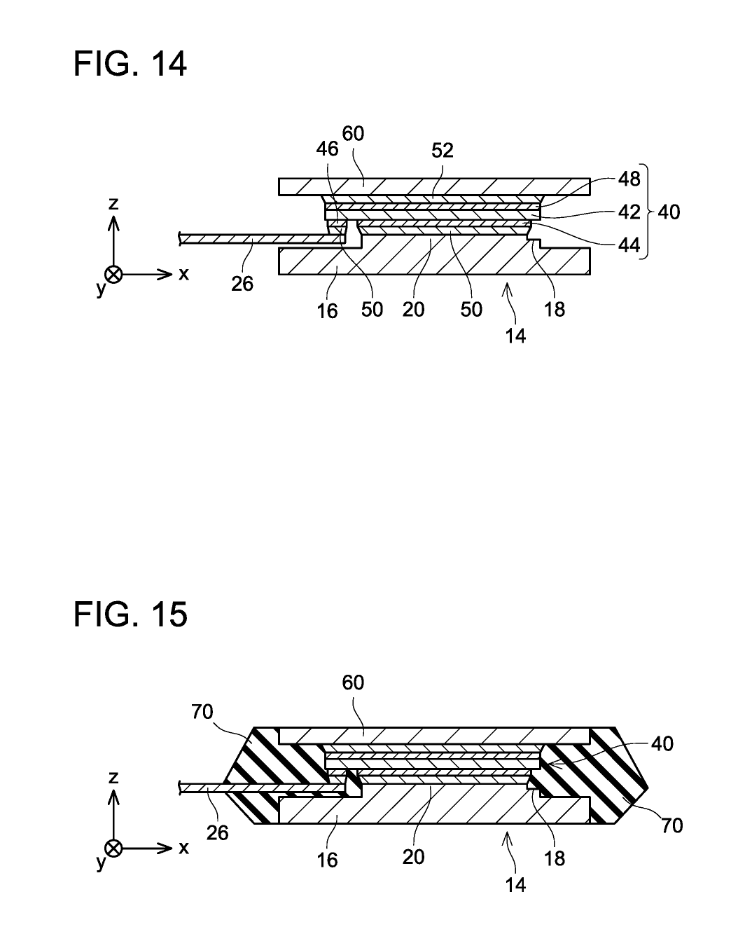

Next, as shown in FIG. 14, a collector terminal 60 is arranged above the semiconductor chip 40, and the collector electrode 48 is connected to the collector terminal 60 by a solder layer 52. The collector terminal 60 is wiring connected to the collector electrode 48, and also serves as a heat dissipating plate for dissipating heat from the collector electrode 48. Further, at this occasion, the main terminal 28b in FIG. 1 is also connected to the collector terminal 60.

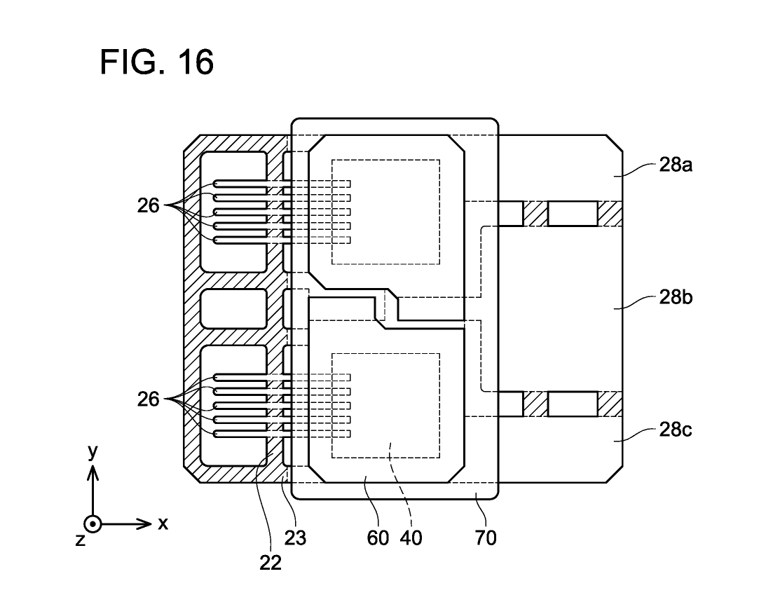

Next, as shown in FIGS. 15 and 16, an insulating resin layer 70 covering the semiconductor chip 40 is formed by injection molding. Portions of the respective terminals which are connected to the semiconductor chip 40 are also covered by the insulating resin layer 70. Each of the signal terminals 26 and each of the main terminals 28a to 28c protrude outside from the insulating resin layer 70.

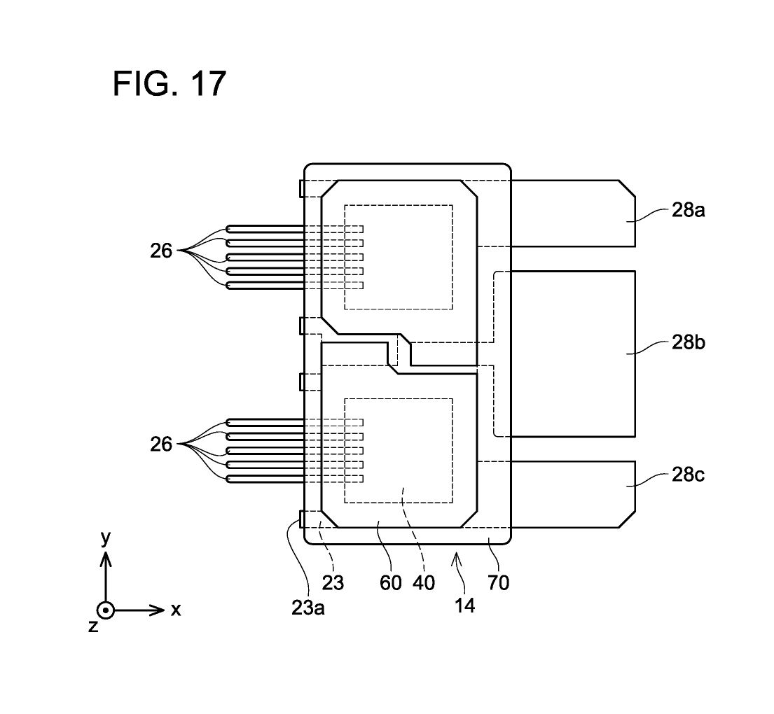

Next, the lead frame 12 is cut at outside of the insulating resin layer 70 to remove a portion hatched with oblique lines in FIG. 16 (the tie bar 22, the suspension lead 23, and the like). Due to this, the signal terminals 26 are separated from each other, and are also separated from the die pad 14. Further, the main terminals 28a to 28c are separated from each other. As a result, a semiconductor device shown in FIG. 17 is completed.

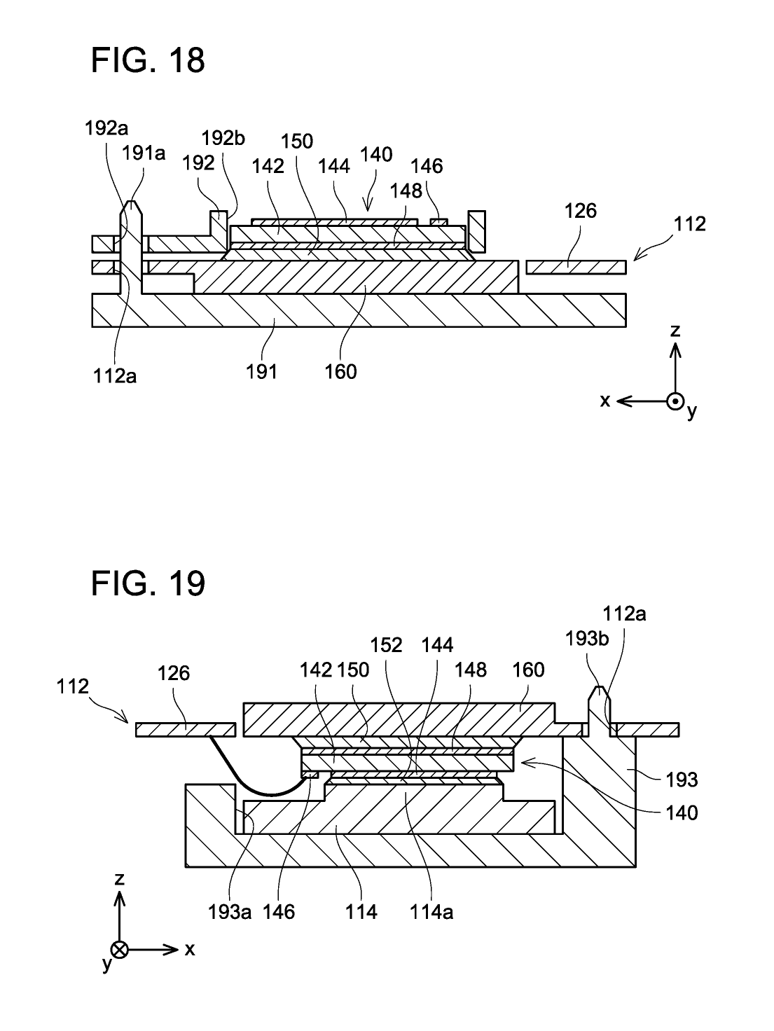

Next, a conventional method of manufacturing a semiconductor device will be described. In the conventional manufacturing method, as shown in FIG. 18, a lead frame 112 in which a collector die pad 160 and signal terminals 126 are integrated is used. Firstly, as shown in FIG. 18, the lead frame 112 is attached onto a first jig 191. The lead frame 112 is positioned with respect to the first jig 191 by inserting a pin 191a of the first jig 191 into a hole 112a provided in the lead frame 112. Next, a second jig 192 is attached onto the lead frame 112. The second jig 192 is positioned with respect to the first jig 191 by inserting the pin 191a of the first jig 191 into a hole 192a of the second jig 192. Next, a semiconductor chip 140 is arranged within a ring portion 192b of the second jig 192. The semiconductor chip 140 includes a semiconductor substrate 142, an emitter electrode 144, signal electrodes 146, and a collector electrode 148. Here, the semiconductor chip 140 is arranged with the collector electrode 148 oriented downward. Thereafter, the collector electrode 148 is connected to the die pad 160 via a solder layer 150. After the collector electrode 148 has been connected to the die pad 160, the first jig 191 and the second jig 192 are detached.

Next, each signal electrode 146 of the semiconductor chip 140 is connected to its corresponding signal terminal 126 of the lead frame 112 by wire bonding.

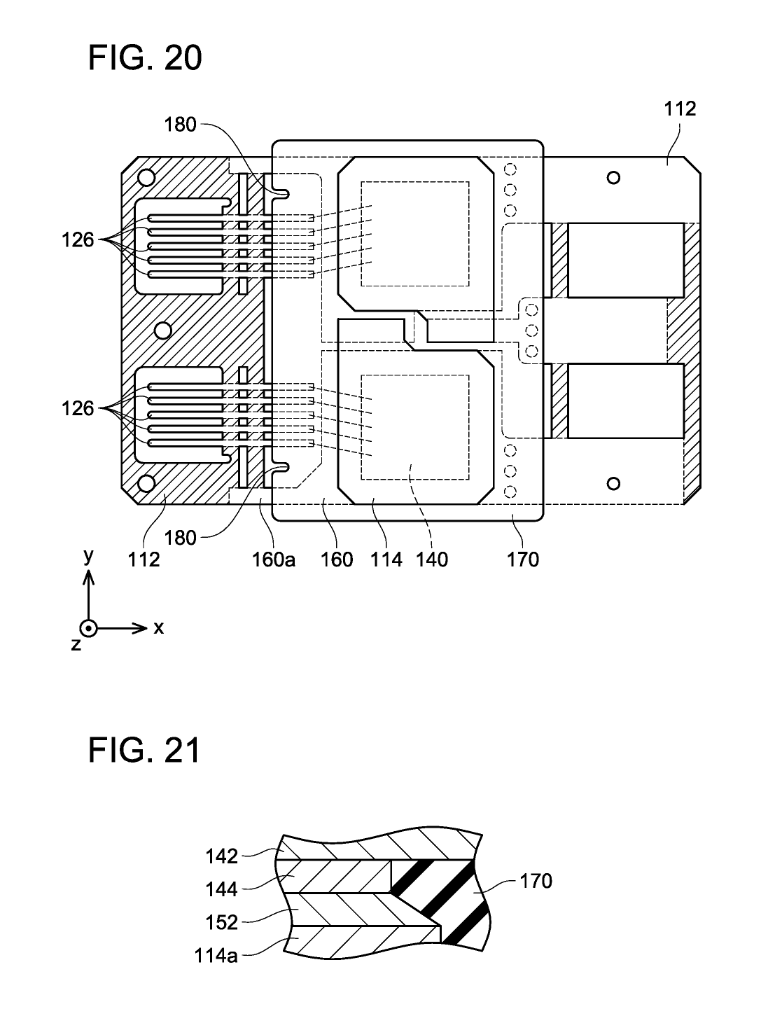

Next, as shown in FIG. 19, an emitter terminal 114 is set to a third jig 193. The third jig 193 includes a recess 193a, and the emitter terminal 114 is arranged in the recess 193a. The emitter terminal 114 is positioned with respect to the third jig 193 by the recess 193a. Next, the component in which the semiconductor chip 140 and the lead frame 112 are connected is attached to the third jig 193. Here, the emitter electrode 144 of the semiconductor chip 140 is arranged above a connection projecting portion 114a of the emitter terminal 114. Here, the lead frame 112 is positioned with respect to the third jig 193 by inserting a pin 193b of the third jig 193 into the hole 112a of the lead frame 112. Thereafter, the emitter electrode 144 is connected to the connection projecting portion 114a via a solder layer 152. Then, as shown in FIG. 20, the semiconductor chip 140 is sealed in an insulating resin layer 170. After the insulating resin layer 170 has been formed, the lead frame 112 is cut at outside of the insulating resin layer 170 to remove a portion hatched with oblique lines in FIG. 20 (a tie bar, a suspension lead, and the like). Thereby, the respective terminals are separated from each other. According to the aforementioned steps, manufacture of the semiconductor device by the conventional method is completed.

In the conventional method, misalignment, which is caused as a collective result of misalignments between the first jig 191 and the lead frame 112, between the first jig 191 and the second jig 192, between the second jig 192 and the semiconductor chip 140, between the third jig 193 and the emitter terminal 114, and between the third jig 193 and the lead frame 112, occurs between the emitter electrode 144 and the connection projecting portion 114a. Since many misalignment factors exist, the misalignment between the emitter electrode 144 and the connection projecting portion 114a is likely to become large. When the misalignment between the emitter electrode 144 and the connection projecting portion 114a is large, it becomes difficult for heat to be transferred to the emitter terminal 114 at a part of the semiconductor chip 140, and the part of the semiconductor chip 140 may locally be subjected to a high temperature. Further, when the misalignment between the emitter electrode 144 and the connection projecting portion 114a is extremely large, the connection projecting portion 114a may protrude outside beyond the emitter electrode 144, as shown in FIG. 21. In this case, the solder layer 152 spreads outside beyond the emitter electrode 144, and it becomes overhanging. In this configuration, the insulating resin layer 170 intrudes into a gap between the solder layer 152 and the semiconductor substrate 142. In this configuration, extremely high stress is applied to the solder layer 152 due to thermal expansion of the insulating resin layer 170 between the solder layer 152 and the semiconductor substrate 142, and thus reliability of the solder layer 152 extremely decreases.

Contrary to this, in the method of the embodiment, misalignments between the jig 30 and the lead frame 12, and between the jig 30 and the semiconductor chip 40 affect a misalignment between the emitter electrode 44 and the connection projecting portion 20. Due to its decreased number of misalignment factors, the misalignment between the emitter electrode 44 and the connection projecting portion 20 can be suppressed. Due to this, heat dissipating performance of the semiconductor device can be stabilized in mass-production of the semiconductor device. Semiconductor devices with poor heat dissipating performance can be prevented from being manufactured. Especially in the method of the embodiment, the emitter electrode 44 is larger than the connection projecting portion 20 as shown in FIG. 9, and thus the occurrence of the case shown in FIG. 21 can be more surely prevented. Therefore, reliability of the solder layer 50 can be secured.

Further, in the conventional method, the lead frame 112 in which the collector die pad 160 and the signal terminals 126 are integrated is used. After the lead frame 112 (i.e., the portions hatched with oblique lines in FIG. 20) has been cut, remaining portions 160a of the suspension lead remain at positions exposed outside the insulating resin layer 170. Since the remaining portions 160a of the suspension lead are connected to the collector die pads 160, the signal terminals 126 (having a potential substantially equal to that of the emitter) and the remaining portions 160a (having a potential equal to that of the collector) exhibit an extremely large potential difference therebetween. Due to this, creeping discharge is likely to occur between the signal terminals 126 and the remaining portions 160a. Therefore, in the conventional method, notches 180 (recesses for making a creeping distance between the remaining portions 160a and the signal terminals 126 longer) need to be provided in a lateral surface of the insulating resin layer 170 between the remaining portions 160a and the signal terminals 126 in order to prevent the creeping discharge. However, with the notches 180 provided, there is a problem that inner stress of the insulating resin layer 170 may become large, and durability of the insulating resin layer 170 against a crack and the like may decrease.

Contrary to this, in the method of the embodiment, the lead frame 12 in which each emitter die pad 14 and its corresponding signal terminals 26 are integrated is used. After the lead frame 12 (i.e., the portions hatched with oblique lines in FIG. 16) has been cut, remaining portions 23a of the suspension lead 23 remain at positions exposed outside the insulating resin layer 70 as shown in FIG. 17. Since the remaining portions 23a are connected to their corresponding emitter die pads 14, the signal terminals 26 (having a potential substantially equal to that of the emitter) and the remaining portions 23a (having a potential equal to that of the emitter) exhibit an extremely small potential difference therebetween. Therefore, creeping discharge is less likely to occur between the remaining portions 23a and the signal terminals 26. Due to this, no notch is needed in a lateral surface of the insulating resin layer 70 between the remaining portions 23a and the signal terminals 26. Therefore, durability of the insulating resin layer 70 against a crack is improved. Further, since no notch is needed, offset between the signal terminals 26 and the signal electrodes 46 along the y-direction is also not needed. Due to this, the suspension lead 23 can be provided on both sides of each set of the plurality of signal terminals 26, and positional accuracy between the signal terminals 26 and the semiconductor chips 40 is improved.

Further, in the manufacturing method of the embodiment, as shown in FIG. 10, the connection projecting portion 20 projects upward from the upper surface of the heat dissipating plate 16 and the clearance is provided between the connection projecting portion 20 and the jig 30, and thus a space can be secured between the signal electrodes 46 and the heat dissipating plate 16. Due to this, wiring (i.e., the signal terminals 26) for the signal electrodes 46 can be arranged in that space. Thus, the wiring for the signal electrodes 46 can suitably be provided.

In the aforementioned embodiment, the semiconductor chip 40 is arranged within the jig 30 after the jig 30 has been attached to the lead frame 12. However, the jig 30 may be attached to the lead frame 12 after the semiconductor chip 40 has been arranged within the jig 30. It should be noted that, in many cases, each of the steps is easily performed stably in the order of the steps according to the embodiment.

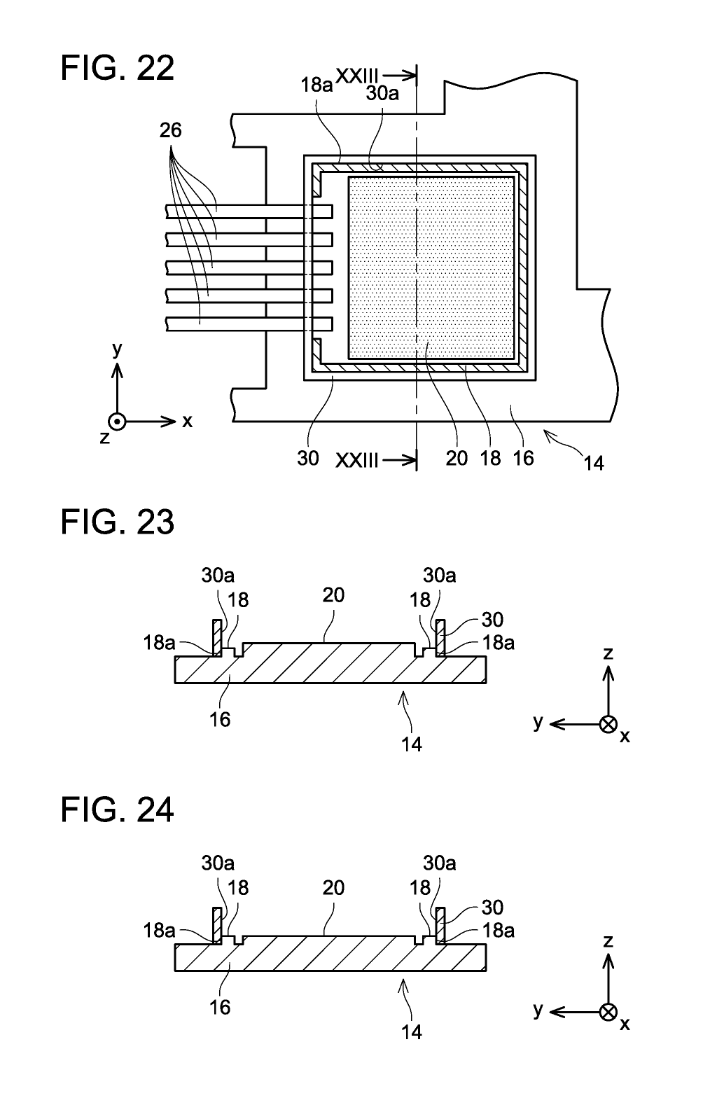

Further, in the aforementioned embodiment, the connection projecting portion 20 and the positioning convex portion 18 are continuous. However, as shown in FIGS. 22 and 23, the positioning convex portion 18 may be arranged at a position separated from the connection projecting portion 20.

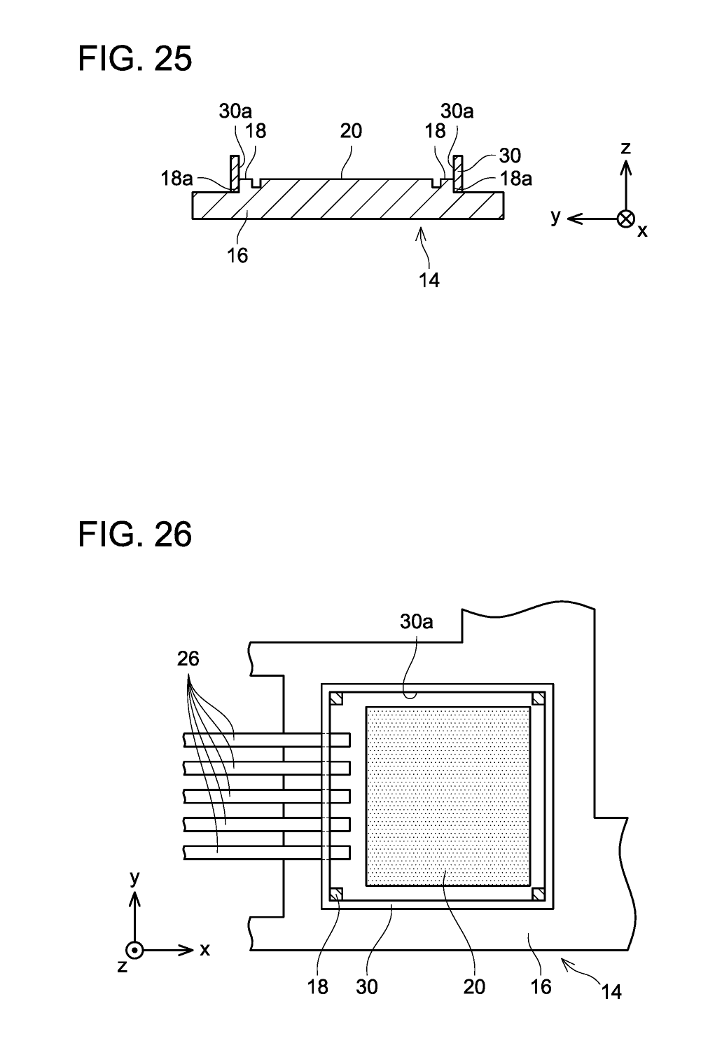

Further, in the aforementioned embodiment, the connection projecting portion 20 is higher than the positioning convex portion 18. However, as shown in FIGS. 24 and 25, the connection projecting portion 20 and the positioning convex portion 18 may be at a same height.

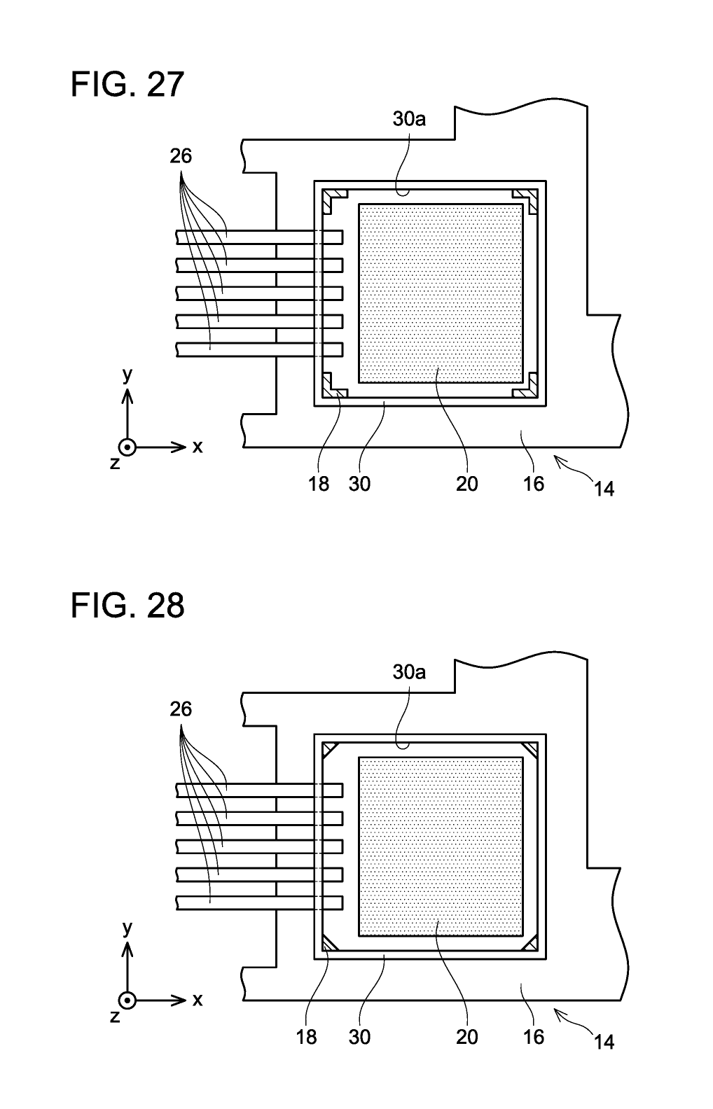

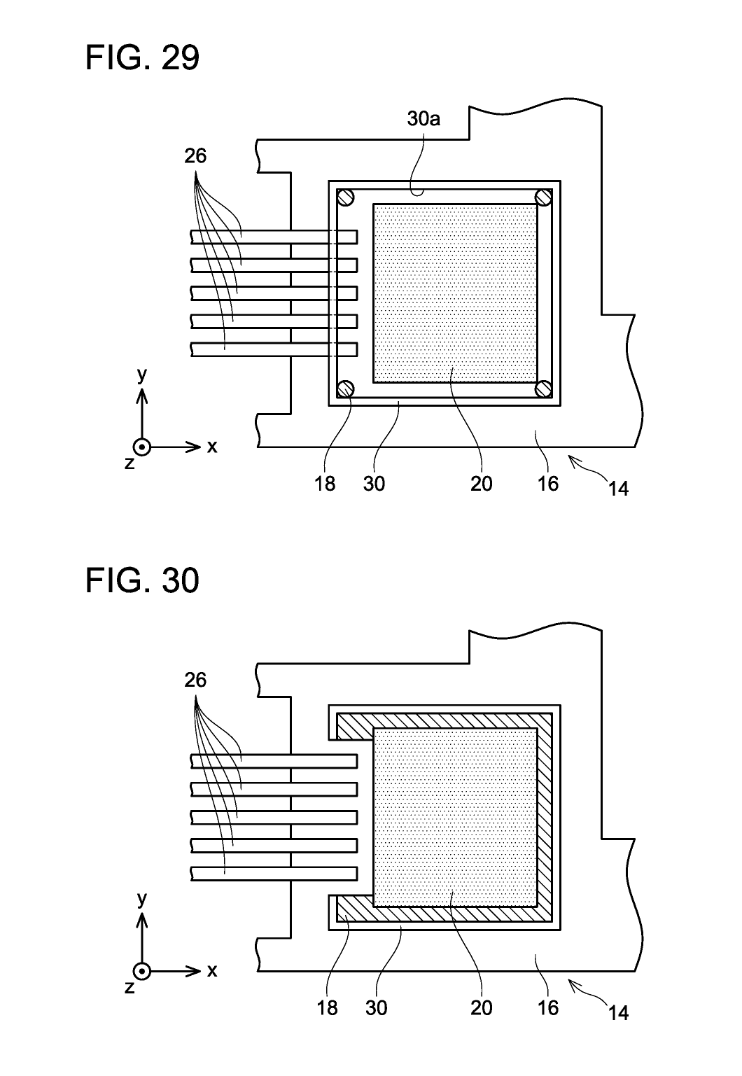

Further, in the aforementioned embodiment, the positioning convex portion 18 is arranged around the connection projecting portion 20. However, as shown in FIGS. 26 to 29, the positioning convex portions 18 may be provided discretely around the connection projecting portion 20. So long as the jig 30 can be positioned, the positioning convex portion(s) 18 may be arranged in any manner.

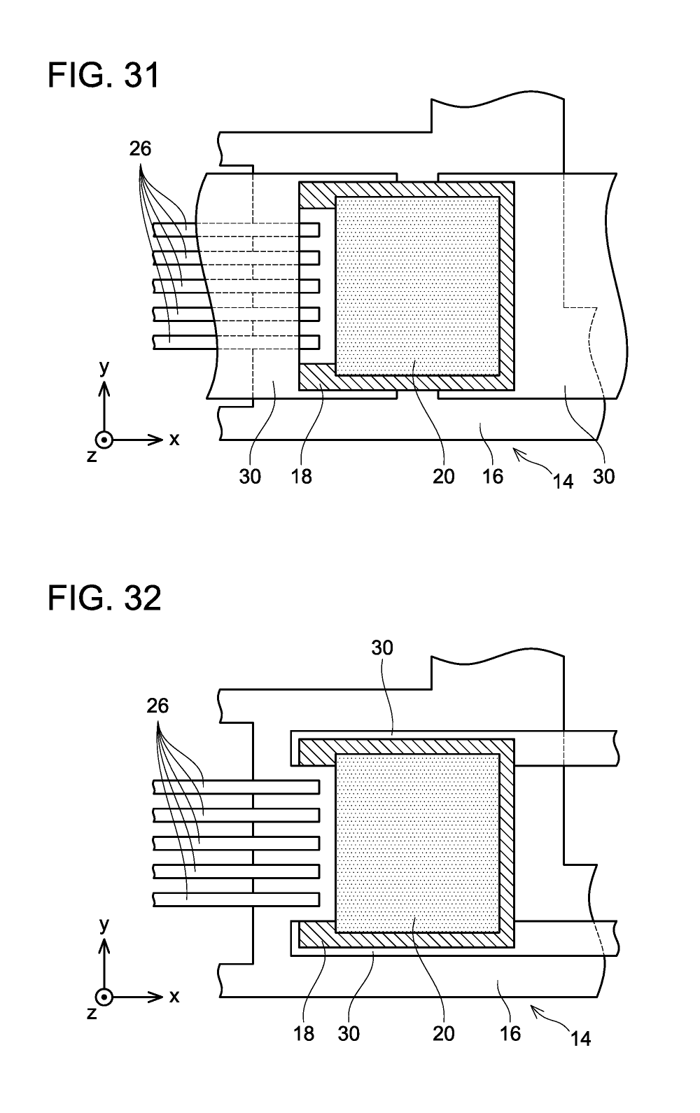

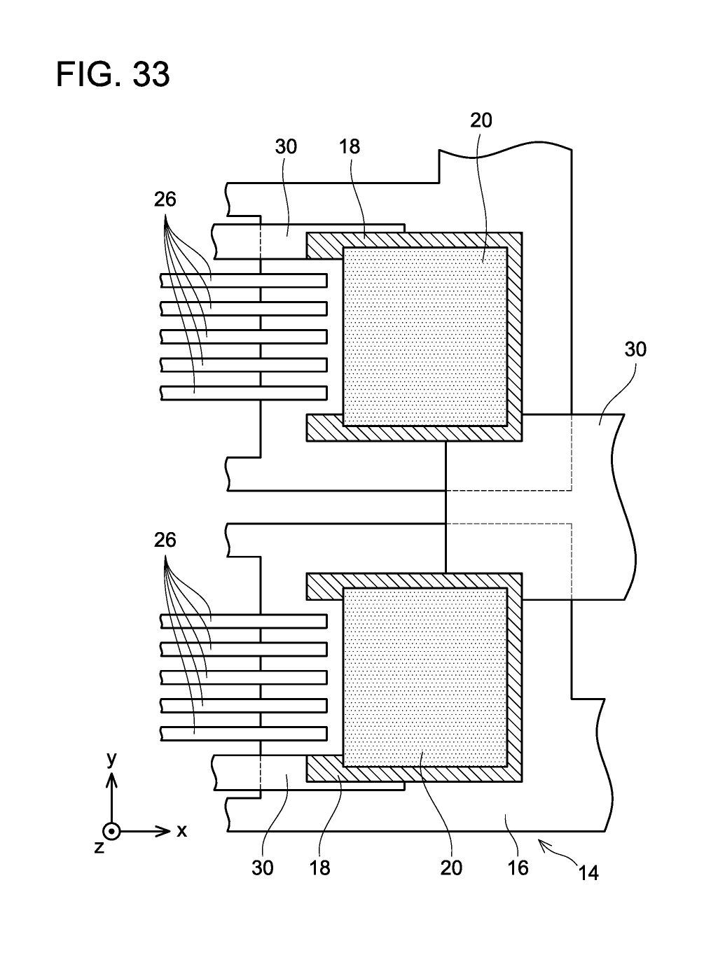

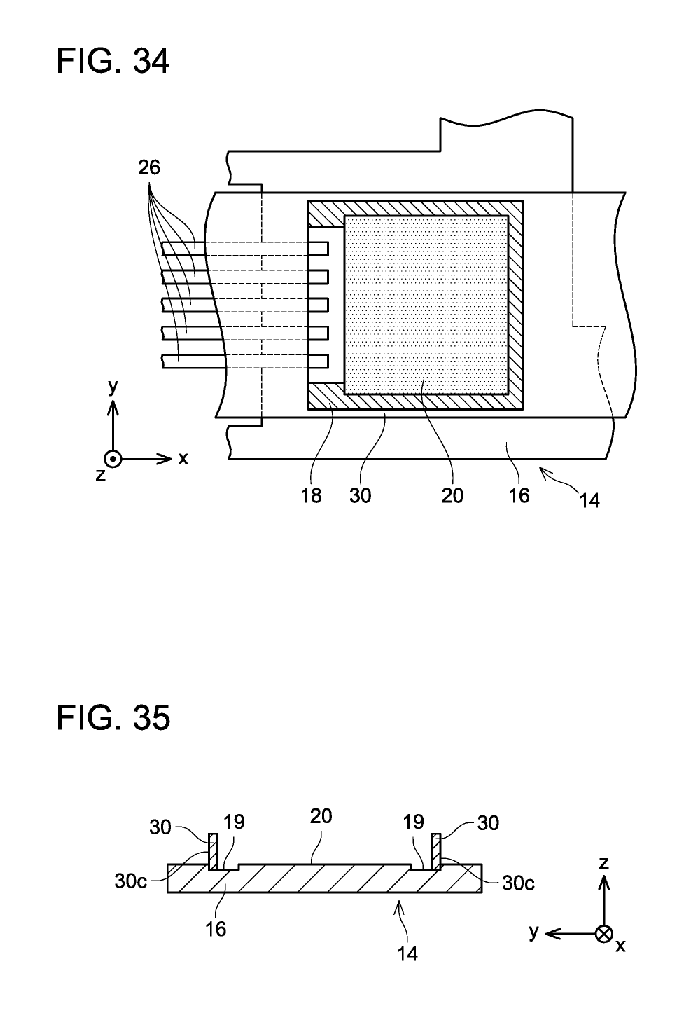

Further, in the aforementioned embodiment, the jig 30 has the ring shape. However, as shown in FIGS. 30 to 33, the jig 30 may have a shape other than the ring shape. FIG. 33 shows a configuration in which two semiconductor chips 40 can be positioned by one jig 30. Even in these configurations, the lead frame 12 and the semiconductor chip(s) 40 can be positioned with respect to each other by the jig 30 engaging to both of the positioning portion of the lead frame 12 and the semiconductor chip(s) 40. Further, as shown in FIG. 34, the jig 30 may be a plate-shaped member provided with a quadrangular hole therein.

Further, in the aforementioned embodiment, an entirety of the upper surface of the positioning convex portion 18 is connected to the solder layer 50. However, a surface treatment having no solder wettability (e.g., surface roughening treatment, etc.) may be performed to an outer peripheral portion of the upper surface of the positioning convex portion 18. In this configuration, a part (a center portion) of the upper surface of the positioning convex portion 18 is connected to the solder layer 50. In this case, the portion of the upper surface of the positioning convex portion 18 that has solder wettability (i.e., the region connected to the solder) is preferably smaller than the emitter electrode 44.

Further, in the aforementioned embodiment, the jig 30 is positioned by the positioning convex portion 18. However, as shown in FIG. 35, a positioning concave portion 19 may be provided instead of the positioning convex portion 18. The jig 30 can be positioned by bringing an outer peripheral surface 30c of the jig 30 into contact with a lateral surface of the positioning concave portion 19.

Some of the technical elements disclosed herein will be listed hereinbelow. It should be noted that the respective technical elements are independent of one another, and are useful solely or in combinations.

In an example of manufacturing method disclosed herein, a positioning portion may include a convex shape. Further, in engaging a jig to the positioning portion, a lateral surface of the jig may be brought into contact with a lateral surface of the convex shape.

In an example of manufacturing method disclosed herein, the positioning portion may include a concave shape. Further, in engaging the jig to the positioning portion, a lateral surface of the jig may be brought into contact with a lateral surface of the concave shape.

In an example of manufacturing method disclosed herein, in a state where the jig is engaged to the positioning portion and a semiconductor chip, in a view along a direction in which the semiconductor chip and a lead frame are stacked, an entirety of a region of a connection projecting portion to which a solder is connected may be located inside a contour of a main electrode.

According to this configuration, the solder connecting the main electrode and the connection projecting portion can be prevented from having an overhanging shape.

In an example of manufacturing method disclosed herein, engaging the jig to the semiconductor chip may be performed after the engaging of the jig to the positioning portion.

In an example of manufacturing method disclosed herein, the main electrode may be an emitter electrode. Further, the semiconductor chip may comprise a signal electrode provided at a surface at which the emitter electrode is provided, and a collector electrode provided at a rear surface located on an opposite side to the emitter electrode. Further, the lead frame may comprise a main body including the connection projecting portion and the positioning portion, and a signal terminal extending from the main body. This manufacturing method may further comprise connecting the signal terminal to the signal electrode; connecting a collector terminal to the collector electrode; forming an insulating resin layer covering the semiconductor chip after the connection projecting portion; and cutting off the signal terminal from the main body after the insulating resin layer is formed. The signal terminal and the collector terminal may be connected to the semiconductor chip.

In this manufacturing method, after the signal terminal has been cut off from the main body, the signal terminal and the main body are exposed to outside of the insulating resin. However, since the signal terminal (i.e., the signal electrode) and the main body (i.e., the emitter electrode) have a small potential difference therebetween, creeping discharge is less likely to occur between the signal terminal and the main body.

While specific examples of the present invention have been described above in detail, these examples are merely illustrative and place no limitation on the scope of the patent claims. The technology described in the patent claims also encompasses various changes and modifications to the specific examples described above. The technical elements explained in the present description or drawings provide technical utility either independently or through various combinations. The present invention is not limited to the combinations described at the time the claims are filed. Further, the purpose of the examples illustrated by the present description or drawings is to satisfy multiple objectives simultaneously, and satisfying any one of those objectives gives technical utility to the present invention.

What is claimed is:

1. A method of manufacturing a semiconductor device by connecting a semiconductor chip to a lead frame using a jig,
the semiconductor chip comprising a main electrode provided at a surface of the semiconductor chip,
the lead frame comprising a connection projecting portion and a positioning portion, the positioning portion including at least one of a convex shape and a concave shape provided around the connection projecting portion,
the method comprising:
engaging the jig to the positioning portion in a state where a clearance is provided between the connection projecting portion and the jig;
engaging the jig to the semiconductor chip; and
connecting the connection projecting portion to the main electrode of the semiconductor chip via solder in a state where the jig is engaged to the positioning portion and the semiconductor chip.

2. The method of claim 1, wherein
the positioning portion includes the convex shape, and
in the engaging of the jig to the positioning portion, a lateral surface of the jig is brought into contact with a lateral surface of the convex shape.

3. The method of claim 1, wherein
the positioning portion includes the concave shape, and
in the engaging of the jig to the positioning portion, a lateral surface of the jig is brought into contact with a lateral surface of the concave shape.

4. The method of claim 1, wherein in the state where the jig is engaged to the positioning portion and the semiconductor chip, in a view along a direction in which the semiconductor chip and the lead frame are stacked, an entirety of a region of the connection projecting portion to which the solder is connected is located inside a contour of the main electrode.

5. The method of claim 1, wherein the engaging of the jig to the semiconductor chip is performed after the engaging of the jig to the positioning portion.

6. The method of claim 1, wherein
the main electrode is an emitter electrode,
the semiconductor chip comprises a signal electrode provided at the surface at which the emitter electrode is provided, and a collector electrode provided at a rear surface located on an opposite side to the emitter electrode,
the lead frame comprises a main body and a signal terminal, the main body includes the connection projecting portion and the positioning portion, and the signal terminal extends from the main body,
the method further comprises:
connecting the signal terminal to the signal electrode;
connecting a collector terminal to the collector electrode;
forming an insulating resin layer covering the semiconductor chip after the connection projecting portion, the signal terminal and the collector terminal are connected to the semiconductor chip; and
cutting off the signal terminal from the main body after the insulating resin layer is formed.

7. A semiconductor device, comprising:
a semiconductor chip including a main electrode provided at a surface of the semiconductor chip; and
a lead frame including a connection projecting portion and a positioning portion, the positioning portion including at least one of a convex shape and a concave shape provided around the connection projecting portion,
wherein
the connection projecting portion is connected to the main electrode via solder.
